(19) United States
(12) Patent Application Publication
(10) Pub. No.: US 2013/0306136 A1
(43) Pub. Date: Nov. 21, 2013

(54) METHOD AND APPARATUS FOR IMPROVING THE EFFICIENCY OF RENEWABLE ENERGY PANELS

(71) Applicant: Jack Reynold Hendrickson, JR., Ann Arbor, MI (US)

(72) Inventor: Jack Reynold Hendrickson, JR., Ann Arbor, MI (US)

(21) Appl. No.: 13/895,291

(22) Filed: May 15, 2013

Related U.S. Application Data
(60) Provisional application No. 61/648,065, filed on May 16, 2012.

(51) Int. Cl. H01L 31/052

(52) U.S. Cl. CPC H01L 31/0521; H01L 31/052
USPC 136/246

(57) ABSTRACT

A method and system for improving the efficiency of renewable energy panels. The invention is comprised of a means for evaporatively misting renewable energy panels and for allowing the renewable energy panels to track the sun. Depending on the environment and installation, the systems can be used individually or together. The invention improves the efficiency of the renewable energy panels by lowering their operating temperature and allowing the panels to optimize energy collection.

### CLAIM OF PRIORITY

None.

### FIELD OF INVENTION

This invention relates, generally, to the class of apparatus for the application of heat. Specifically apparatus having means to direct solar radiation and support means for an article to be heated by the directed.

### BACKGROUND OF INVENTION

Currently, most of the world's economies are reliant heavily on fossil fuels. Fossil fuels have many drawbacks. Fossil fuels pollute and are largely responsible for deleterious Global Warming, commonly referred to as the greenhouse effect. Additionally, pollution from fossil fuels makes air in many major cities, such as Mexico City, Beijing, and Los Angeles, unhealthy to breathe for many people. Power-lines, refineries, and pipelines are also ugly ubiquitous installations. The procurement of fossil fuels, whether in mining coal or drilling for petroleum, is inherently polluting. Mountaintop removal for coal and hydraulic fracturing (“fracking”) for natural gas both contaminate ground water, endangering the life and health of those nearby. Drilling for and transportation of petroleum, coal and gas are also fraught with hazard witness the BP drilling catastrophe in the Gulf of Mexico in 2010, the grounding of the Exxon Valdez in 1989, or the pipeline rupture in Arkansas in 2013.

Fossil fuels give undue influence to governments who control large exportable quantities. The majority of exported crude comes from areas of the world with known unstable, unpopular governments, and/or those in tension with the West. For instance, much of the imported oil America receives comes from the Middle East, Venezuela, Angola and Nigeria—all meeting the above description. Many oil-exporting Middle East regimes are openly hostile to and contemptuous of the United States, notably Iran. Many other autocratic “friendly” regimes such as Saudi Arabia and Kuwait are clearly unstable and vulnerable, in light of the Arab Spring. The U.S. secures additional petroleum from Venezuela, which in recent history has badly strained relations with the U.S. Western Europe procures much of its fossil fuels (natural gas) from Russia, an historic competitor with the West. Even without these serious national security issues, to the extent that fossil fuels are imported needlessly, a nation exports its wealth, needlessly.

Fossil fuels are also becoming increasingly scarce, meaning that their price is rising. The United States International Energy Agency estimates that 2006 was the peak year of petroleum production. The global output of petroleum will now slowly decline. Meanwhile, the BRIC countries (Brazil, Russia, India, and China) are rapidly growing, driving demand for petroleum upward. This has led to volatility in the oil markets, with the cost of a barrel of oil peaking at $140 in 2008. Since then, the price for crude oil has varied from a low of $70 per barrel to a high of $110 per barrel; such swings of 50% in a basic commodity are painful all by themselves. All indicators are that the price of a wide variety of fossil fuels will steadily increase, faster than other goods, until they are exhausted.

In response to these drawbacks of fossil fuels, industry, governments, and academic institutions have been pouring resources into finding renewable energy sources for years. To date, the results are mixed. Current renewable resources all have three drawbacks: cost, environmental impact, and consistency of availability. The cost of a renewable energy source is measured by various metrics: Return on Investment (“ROI”), cost per kilowatt hour (“CPkWH”), levelized cost of energy (“LCE”), etc. In order to be competitive, the CPkWH must be comparable to that of fossil fuel. Alternately, the ROI (reciprocal of payback period) must be realistic with a short number of payback years. Currently, no renewable sources are cheaper than fossil fuels over the short-run (3 years or less).

Specifically, photovoltaic panels are far from optimized, in that they have significant environmental impact, limited hours of operation, and suppressed operating efficiencies. Photovoltaic (“PV”) panels, like many renewable energy sources, have a significant environmental impact. Environmental impact means not only pollution, but also a visible, intrusive installation foot-print. For example, in order to generate usable quantities of solar energy using PV panels, one needs a sunny location and a very large surface area due to their characteristic conversion efficiencies of 20% or less.

Other operational limitations exist for PV panels. Most types of PV only provide significant power with direct beam sunlight. Yet peak electricity demand is typically in hours around and after dusk, just when PV loses its generating capacity. In areas in which snow fall is common, PV panels stop operating after a snow fall, until such time as the snow pack is removed from the surface of the PV panel. When PV arrays have a cloud pass overhead, the electrical grid, suddenly, must be able to provide power using other, more reliable means. Furthermore, those types of PV and thermal panels which can collect the diffuse radiation under a cloud deck are unable to rapidly change tilt angle toward horizontal to maximize the 180° of incoming diffuse radiation. Those arrays which are fixed or otherwise unable to adjust tilt in this way suffer significant losses of potential performance during each period of cloud cover. In worst case scenarios, this performance variability can lead to grid destabilization, threatening regional blackouts. Moreover, the grid requires 100% of its former fossil capacity as backup, since PV panels have zero baseline stability. The inconsistency of power generation greatly reduces the appeal of these renewable energy resources.

Perhaps most important, the actual efficiency achieved using PV panels is much lower than the rated efficiency. The output power efficiency of PV panels is normally measured, for rating purposes, at an idealized 25° C. This is a self-serving measurement, in that the selected temperature for the rating measurement also corresponds with the peak output of the panel. In reality, PV panels are exposed to ambient environments between −40° F. and 140° F., resulting in non-ideal performance. PV panels become less efficient as they are heated. In a sunny, warm location, in which a PV panel operates at or near 60° C. (140° F.), its output will be suppressed by as much as 40% when compared to its rated efficiency. This means that an installed system with a rated output of 10 kW would, in actuality, operate, during the early and mid-afternoon period of peak potential, at between 6 kW and 8 kW, depending on ambient conditions. Rarely, then, will ambient thermal conditions permit PV panels from operating at rated output.

Additionally, the peak output of PV panels is only briefly available, while the rays of sunshine are orthogonal to the face of the PV panel. For the remainder of the day, the PV panel will produce less than its rated amount of power. How much less depends on a number of factors: the cleanliness of the PV panel surface; whether the PV panel surface has any scratches; the reflectivity, refraction index and transmissivity of the PV panel's surface material; the latitude of the installation; the season; and the ambient weather conditions, inter alia. These factors of efficiency degradation also affect thermal solar panels, albeit to a lesser extent. Typically, solar thermal panel installations are focused on collecting warm heat energy only, limiting their functionality to approximately one-half of the day.

All types of panels, whether PV, thermal or other, suffer losses of efficiency from pollution, dust, leaves, and even bird droppings. All these contribute to prevent sunlight from reaching the working surfaces of the panel. The more dirt, the lower the amount of energy a panel gathers. According to the National Renewable Energy laboratory, losses due to surface contamination may range as high as 25% in some areas. Individual dealers have reported losses that exceed even this number, due to customers failing to clean their panels. Improper cleaning can also impair performance, resulting, in extreme cases, in a polarity inversion. When contamination build-up causes a polarity inversion, the performance of an entire array can be affected.

Clearly, then, the art is searching, still, for an optimized renewable energy resource. By merely allowing new and existing PV, thermal and other renewable energy panels to achieve their rated efficiency for more hours of the day, the generating capacity of renewable energy panels would increase significantly. Additionally, helping PV panels to generate electricity, and thermal panels to generate heat immediately after snow storms would further increase the generating capacity of installed panels. This necessitates a system that lowers the operating temperature of panels on hot days, melts snow immediately after a snow-fall, and removes grime and other surface contaminates.

Lastly, if the renewable energy panels could track the sun, the amount of radiant energy absorbed in a given day would increase significantly. Tracking could either be simple, such as a single-axis horizontal tracking mechanism, taking advantage of the diurnal cycle; or it could be more complex, such as a two-axis tracking mechanism that adjusts for both season and time-of-day. The improvement in total energy generation depends on the tracking system deployed, the accuracy of the tracking mechanism, the energy required to run the tracking system, and the latitude of the installation.

The human body cools itself in warm climates through perspiration. Dogs achieve evaporative cooling via exhaling/inhaling across the moisture brought to their tongues and mouths. Likewise, evaporative cooling is a well-known alternative method for cooling air in patio settings, used in many warm locations. In the US Southwest, “swamp coolers” using this principle were long used to cool indoor air, since the resultant relative humidity gain was acceptable in such dry climates. Evaporative cooling can be extended from making cool air to cooling the surface of a hot object. For example, by misting the surface of a PV panel on a warm, sunny day, its output at peak times (10 a.m. until 2 p.m.) improves by 16%-25%. This improvement in output is the direct result of a lower operating temperature caused by evaporative cooling of the PV panel's upper surface.

Mists, sprays and trickles can also be used to reduce or eliminate snow packs, due to melt-off and the change in surface tension between the panel and the snow-pack. A fine mist of water immediately reduces a snow pack by melting the surface snow. A relatively small amount of water can be made to melt a large amount of snow, depending on the ambient temperature of the water, air, and snow. The trickle of water changes the surface tension between the snow and the panel, creating a slippery slope underneath the snow. With the proper panel tilt and surface tension, the snow will slide off in a mass.

Fine sprays or mists can also be used to wash or clean surfaces without contact. Car washes are an extreme example of this concept. A fine spray of water, repeated, can clean a grimy surface without any contact, as occurs with rainfall. Since rainfall is an intermittent and unreliable dust-remover, programmatic approaches are considerably more effective. Adding surfactants or detergents to the spray improves the results.

A tracking mechanism for renewable energy panels requires mounts that can, on a single axis, rotate slowly parallel with the horizon; and mounts that can rotate about the mounting system's center of gravity. Rotating about a single axis, parallel to the horizon, allows the panel to track the sun during the course of the day. Rotating about the center of gravity allows the panel to make both gross and fine adjustments: gross adjustments can be made to compensate for the time of the year, aiming the panel directly at the sun; fine adjustments can be made on a minute-by-minute basis in response to cloud cover and other emergent conditions. Such a tracking system is compatible with new technologies, such as thermal panels that collect cold thermal energy, available in the winter and at night. The tracking system can aim such panels to optimize for cold thermal energy collection, while simultaneously protecting the panel from wind damage. In order to be useful, the system would have to be weather-proof, low-energy, accurate, and quiet, so as not to disturb owners and neighbors.

### SUMMARY OF THE INVENTION

The present invention is a simple system, intended for use with new or existing PV, thermal or other renewable energy panel installations. The system can mist the panels and allow the panels to track, in accordance with a variety of environmental inputs. The misting and tracking can be used, either individually or together, in order to improve the efficiency of the panel. The misting system is easily integrated into new panel installations and retro-fitted into existing panel installations. It has a plurality of small nozzles, which are mountable to the top of the panels. The nozzles are fed by a piping system, which can be fabricated from PVC, PEX, ABS, copper, or other suitable plumbing material. The nozzles are controlled by a controller, which determines the appropriate amount of misting.

The misting system can have accessories to improve performance, depending on the environment. In climates with frequent winter snow, a warming reservoir and trickling nozzles can be added to the system, to warm the mist and create slippery slope, respectively. The warming reservoir would be incorporated into the system between the piping and the nozzles. The warmed mist can then be used to melt snow on the panel from the upper layer on down. The trickling option additionally encourages the entire snow mass to slide, due to gravity, all at once. This accessory would come with an additional controller, to control, amongst other things, the heating of the water, and to sense whether or not snow is on the panel.

In dusty, dry climates, a reservoir for surfactant or detergent can be added to the system, to allow the mist to remove dust and grime. This accessory would come with an additional controller, to control, amongst other things, the level of surfactant or detergent, to sense the cleanliness of the panels, and to establish when the panels are clean enough.

The system would also come with an optional mounting system that allows the panels to track the sun. The tracking system would have two methods by which to improve panel efficiency: first, the system would improve direct radiant energy capture by allowing the panel to remain orthogonal to the sun's rays; and second, the system would quickly adjust tilt to the horizontal during periods of diffuse radiance (cloud cover).

The mounting system that enables tracking would have two embodiments: a pole-type mount and floating-type mount With a pole-type mount, the panels would be fastened to a cross-member. The cross-member would fasten to a pole at a rotational coupling. The rotational coupling would be motor-driven or cable-driven, allowing the panels to be rotated about the coupling. The coupling could be oriented in multiple ways, to allow for optimizing the rotational aspects of the tracking system. The pole would be on a rotational mount, also. The combined movement of the coupling and the pole's rotational mount would allow the tracking system to optimize the position of panels in order to maximize energy absorption. Among the factors that the tracking system would account for are time of day, time of year, cloud-cover, wind, and radiant temperature.

With a floating-type mount, the panels would be mounted to a plane member. In one embodiment, the plane member would be positioned over a water tank. In another embodiment, the plane member would be positioned over a shallow pool, pond, or other suitable body of water. The underside of the plane member would be constructed so as to make the plane member, mounts and panels float on top of the water. The panels could be positioned with pumps actuated by controllers. The controllers would use an algorithm to optimize the position of the panels, taking inputs, that include, but are not limited to, time of day, date, cloud cover, temperature, and latitude.

Another embodiment of this type of mount, called the turntable type, would be having the plane member attached to a turntable. The turntable would ride on bearings and would be driven by an electric motor. The controllers would use largely the same algorithm inputs, as mentioned above.

### BRIEF DESCRIPTION OF THE DRAWINGS

There are nine (9) figures used to illustrate the invention.

FIG. 1 shows a prospective view of the combined misting and tracking systems.

FIG. 2 shows a top view of the combined misting and tracking system.

FIG. 3 shows a front view of the combined misting and tracking system.

FIG. 4 shows a side view of the combined misting and tracking system, highlighting another of the potential motions of the rotational coupling.

FIG. 5 shows a prospective view of the misting system being retrofitted to an existing panel installation on a residential or other sloping rooftop.

FIG. 6 shows an isolated prospective view of the misting system on a panel installation.

FIG. 7 shows an isolated prospective view of an alternative embodiment of the misting system.

FIG. 8 shows a perspective view of a turntable-type tracking system, with a turntable member supporting the renewable energy panels.

FIG. 9 shows a perspective view of a floating-type tracking system with the plane member positioned over a water storage tank.

### DETAILED DESCRIPTION OF THE PREFERRED EMBODIMENTS

The detailed description is intended to illustrate the present invention, without, in any way, limiting its scope.

The invention is a system for a PV, thermal or other panel implementation of a renewable energy system for use in residential, commercial, and industrial buildings. The system is a misting and tracking system, for use in conjunction with renewable energy panels, and intended to improve the efficiency of said panels. The system is tailorable and scalable. The system can be implemented as just an evaporative misting system, just a solar tracking system, or both. The system has embodiments which will work for new installations and embodiments which will work for existing PV panel installations.

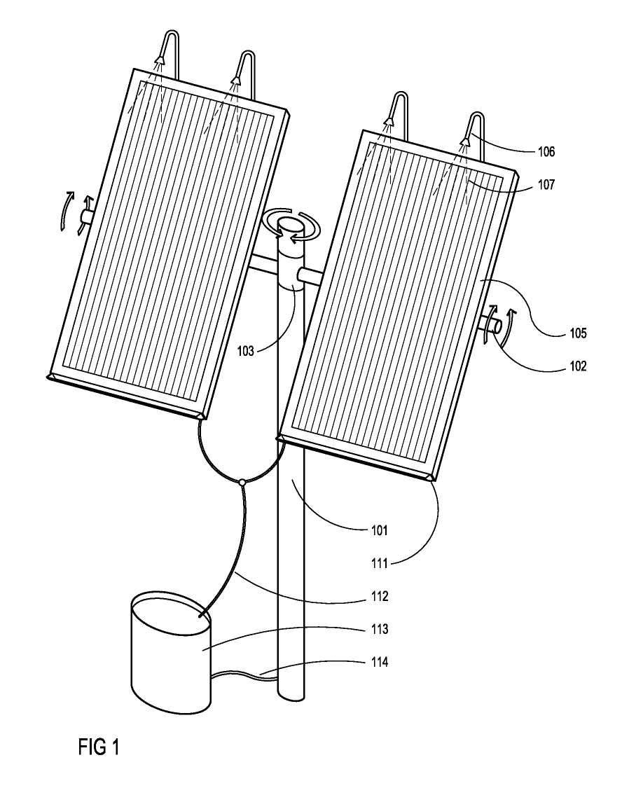

FIG. 1 shows a perspective view of the system mounted with solar panels 105. The panels 105 can be PV, solar thermal, or other type of solar panels. The panels 105 can be constructed flat, parabolic, 3-D/cubic, or other types of mountable constructions. The system allows for panels 105 to track the sun. Various types of panels 105 can be mounted on a pole 101. The pole 101 can be fabricated from any suitable construction material: steel, aluminum, PVC, etc. The mounting pole 101 can be specifically installed for the mounting of panels, or already existing. The cross-member 102, also, can be fabricated from any suitable construction material. The cross-member 102 is designed to handle the load imposed by the panels 105, allowing for rotation about an axis, in order to facilitate tracking the sun. The cross-member 102 is connected to the mounting pole 101 at a housed coupling 103. The housed coupling 103 allows the cross-member 102 and panel 105 to pivot about the axis of the cross-member 102. The tracking system is controlled by a controller, which will adjust the housed coupling 103, to optimize output for a number of input variables, including, but not limited to, time of day, shading by nearby object, wind losses, and wind shear.

Continuing with FIG. 1, the system also includes a method and apparatus to provide the panels 105 with an evaporative mist 107. The evaporative mist 107 is supplied by a nozzle 106. The nozzle 106 is supplied water by a system of piping 114, which is connected to a reservoir or barrel 113. Alternately, the piping 114 can be connected directly to a municipal water source (not shown). When using a reservoir or barrel 113, the system relies on a pump to create pressure in the piping 114 to get the mist 107 to the nozzle 106. The system has a rain gutter 111, that funnels run-off into a series of tubes 112, which feeds the reservoir or barrel 113.

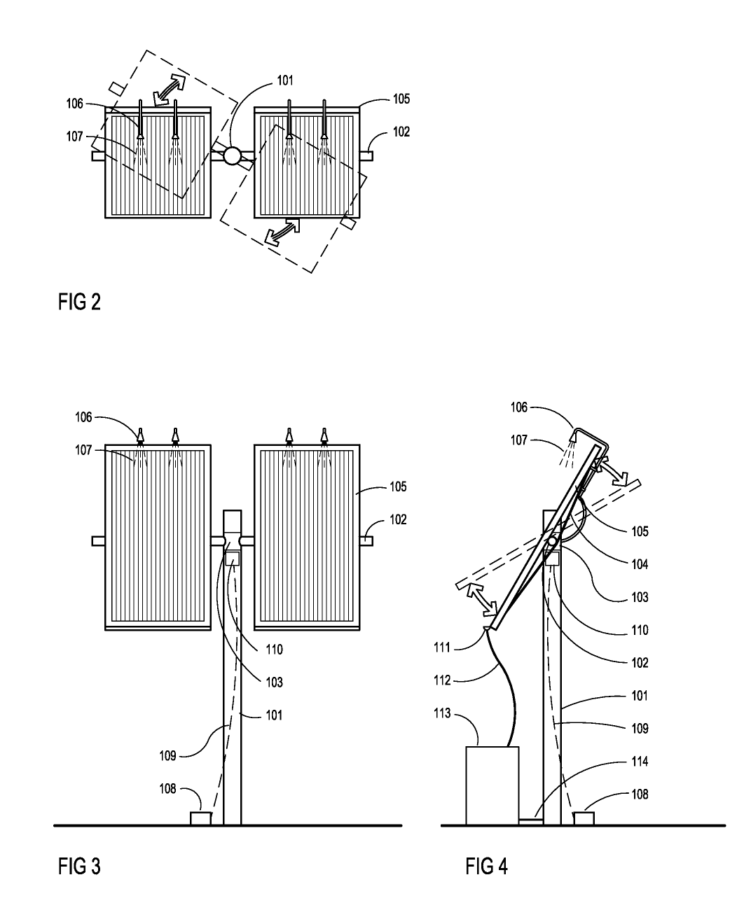

FIG. 2 shows a top view of the system, highlighting the tracking capabilities. The mounting pole 101 can rotate about its axis, allowing the panel array 105 to pivot. The cross-member 102 and nozzles 106 are constructed so that they pivot with the system. This allows the system to track the sun and be evaporatively misted 107, simultaneously.

FIG. 3 is a front view of the system. In this view, the drive and control mechanism 108, 110 is shown. The drive and control mechanism 108 can be mounted to the ground, roof, or other appropriate place. As an alternative embodiment, the drive and control mechanism 110 can be pole mounted. The drive and control mechanism 108, 110 controls a cable-pulley system 109, which is capable of adjusting both degrees of freedom. The cable-pulley system 109 can be housed inside of a hollow mounting pole 101, or can be externally mounted in a weather-secured fashion.

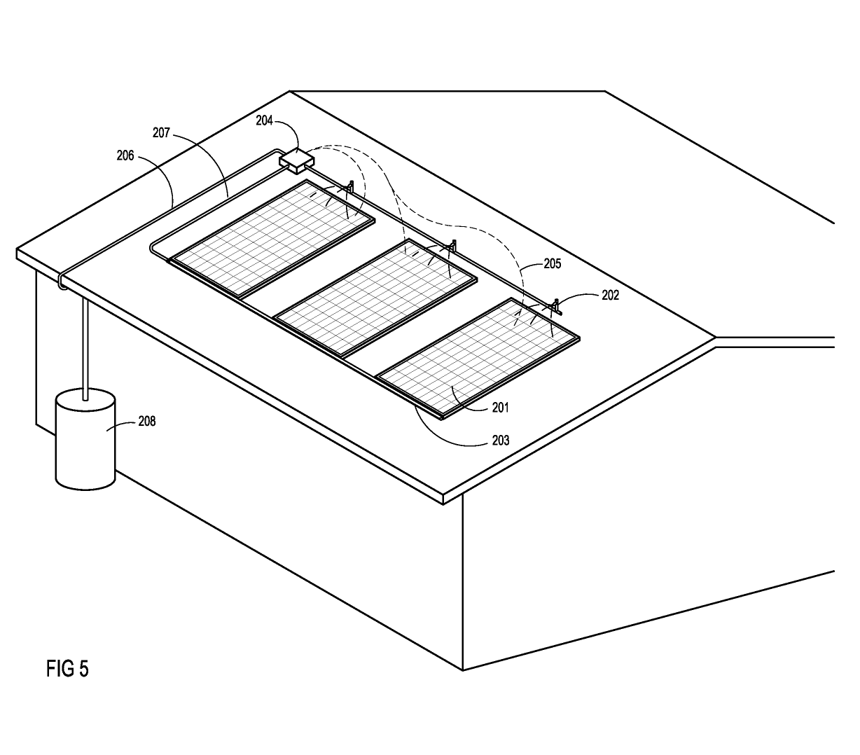

FIG. 4 is a side view of the tracking and misting system. This view shows all of the elements described: mounting pole 101; cross-member 102; housed coupling 103; piping 104, 114; panel 105; nozzle 106; evaporative misting 107; drive and control mechanism 108, 110; cable-pulley system 109; a rain gutter 111; and tubing 112 to funnel run-off into a reservoir or barrel 113.

FIG. 5 shows a perspective view of a new or existing panel 201 installation with a misting system. The misting system can be easily retro-fitted to an existing PV or thermal solar panel installation. The system has a plurality of nozzles 202, which are fed by piping 206. The system contains a plurality of sensors 205. The run-off, either from rain or misting, is captured in a gutter 203 and fed to a piping system 207. The system has a control and pump mechanism 204, which allows either automatic control or manual control in order to regulate the flow of water out of or into the reservoir or barrel 208.

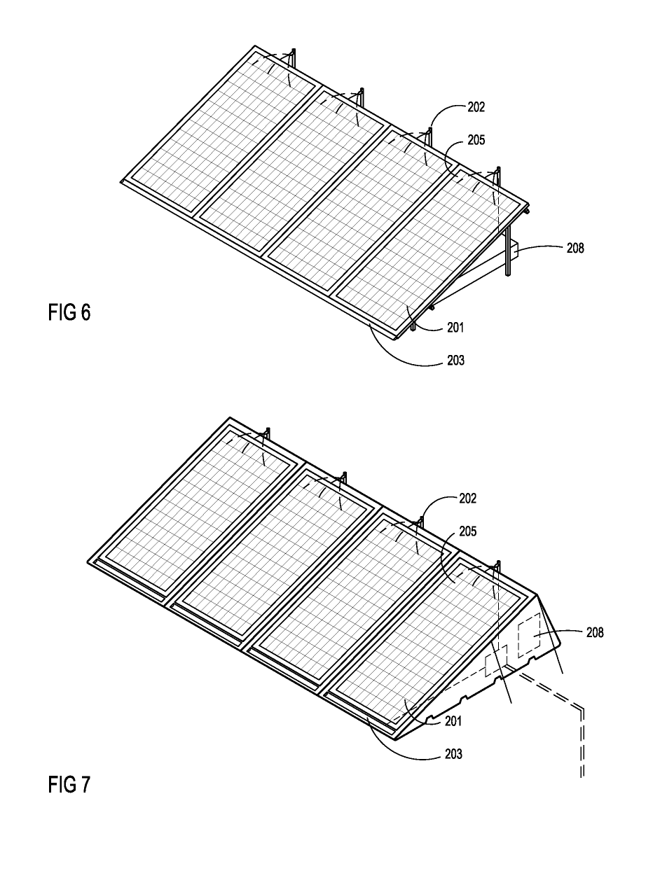

FIG. 6 shows an alternative embodiment of the misting system, in which the reservoir or barrel 208, is mounted under the panel installation. FIG. 7 shows another alternative embodiment of the misting system, in which the panels are mounted on wedges 208. The wedge is integral 208, containing in its bulk a reservoir or barrel 208, which allows the system to have a nearby water supply. The gutter system 203 in both of these embodiments feeds the run-off back to the reservoir or barrel 208. Both of these systems are controlled, in part, by a plurality of sensors 205 mounted to the panels.

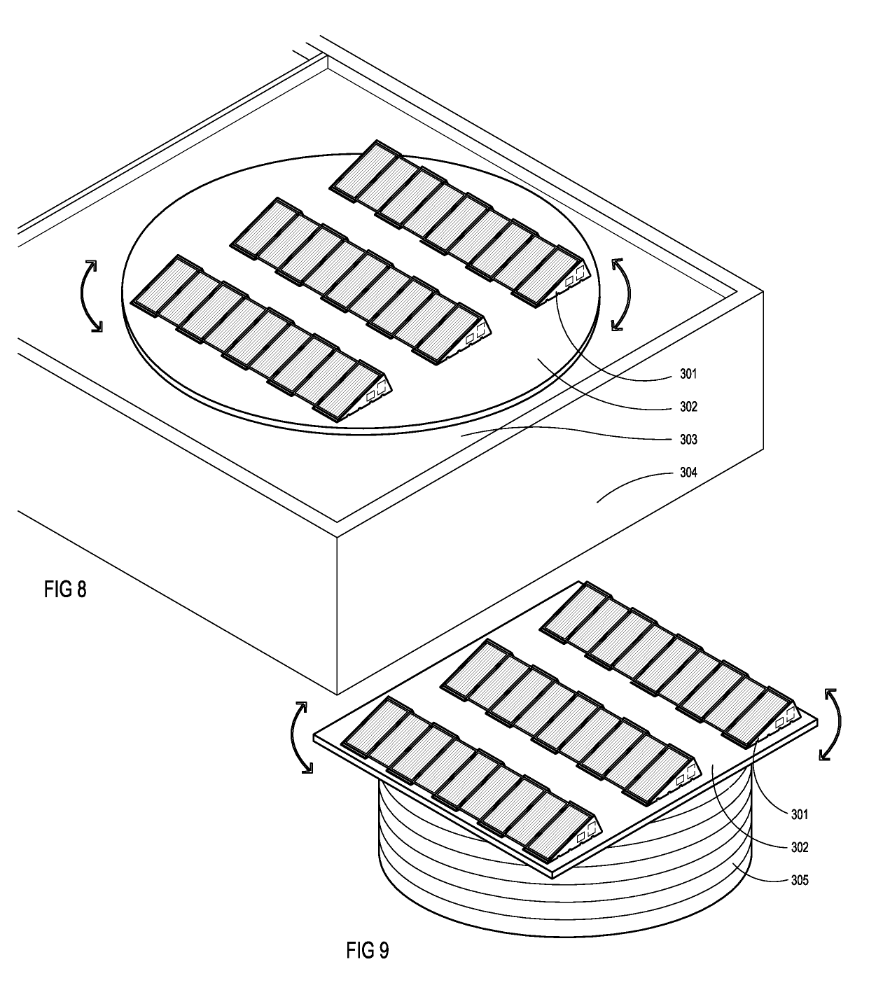

FIG. 8 shows a turntable-type tracking system. A plurality of renewable energy panels 301 are secured to a turntable member 302. The turntable member 302 is positioned over an upper surface 303. The housing 304 of the overall system supports the upper surface 303, and contains the support, bearings, drive system, and controller needed to move the turntable 302 so that the renewable energy panels 301 track the sun.

FIG. 9 shows a float-type tracking system. A plurality of renewable energy panels 301 are secured to a turntable member 302. The turntable member 302 is positioned over a water storage tank 305. The water storage tank 305 is filled such that the turntable member 302 floats on the water in the water storage tank 305. The system includes pumps and controllers (not shown) needed to move the turntable 302 so that the renewable energy panels 301 track the sun.

We claim:

1. A PV or thermal solar panel system which allows for evaporative misting of ground- or roof-mounted renewable energy panels, comprising a plurality of PV or thermal solar panels; a pump suitable for pumping fluid; piping suitable for fluid transport; a plurality of nozzles located above, and in proximity with, the PV or thermal solar panels; a controller; a plurality of sensors to monitor temperature and incident sunshine; and software for determining whether or not the PV or thermal solar panels need to be misted.

2. The invention described in 1, in which at least some of the water is supplied by a reservoir or barrel.

3. The invention described in 2, in which the reservoir or barrel is supplied with water through a system of gutters and tubing, that collects run-off waste water from the face of the PV or thermal solar panels.

4. A system which allows for ground- or roof-mounted PV or thermal solar panels to track the sun, comprised of a plurality of PV or thermal solar panels; a plurality of sensors for monitoring the intensity and angle of the sunshine; one or more mounting poles, an equal number of cross-member poles, and an equal number of housed couplings for attaching the cross-member poles to the mounting poles; a controller; a means for moving the mounting and cross-member poles; and software for determining the appropriate angle for the PV or thermal solar panels.

5. The invention described in 4, in which the means for moving the mounting and cross-member poles is a servo motor.

6. The invention described in 5, in which the means for moving the mounting and cross-member poles additionally uses pulleys and cables, actuated by the servo motor, to position the panels.

7. The invention described in 4, which additionally has a means for evaporative misting of ground- or roof-mounted PV or thermal solar panels, comprising a pump suitable for pumping fluid; piping suitable for fluid transport; a plurality of nozzles located above, and in proximity with, the PV or thermal solar panels; a controller; a plurality of sensors to monitor temperature and incident sunshine; and software for determining whether or not the PV or thermal solar panels need to be misted.

8. The invention described in 6, in which it is comprised of a plane member; mounting elements to hold renewable energy panels to the plane member; a water reservoir upon which the plane member floats; a plurality of pumps used to rotate the plane member; and a controller or controllers which control the pumps, allowing the panels to be optimally positioned.

9. A system which allows for ground- or roof-mounted PV or thermal solar panels to track the sun, comprised of a plurality of PV or thermal solar panels; a body of water capable of providing buoyancy to the PV or thermal solar panels; a platform on which the PV or thermal solar panels are mounted, which floats in the body of water; a controller; a pump; a plurality of water outlets controlled by the controller; and software that adjusts the amount of water coming out of the water outlets, so that the PV or thermal solar panels are correctly positioned with respect to the sun.

10. The invention described in 9, in which the body of water is a storage tank on top of which the PV or thermal solar panels are mounted.
